(19) United States
(12) Patent Application Publication
(10) Pub. No.: US 2025/0194263 A1
(43) Pub. Date: Jun. 12, 2025

(54) RETROFITTING A THIN FILM TO A SOLAR SYSTEM

(71) Applicant: Conti SPE, LLC, Summit, NJ (US)

(72) Inventors: Kurt G. CONTI, New Providence, NJ (US); Cullin J. WIBLE, Austin, TX (US)

(73) Assignee: Conti SPE, LLC, Summit, NJ (US)

(21) Appl. No.: 18/686,301

(22) PCT Filed: Aug. 22, 2022
(86) PCT No.: PCT/US2022/041026

§ 371 Date: Feb. 23, 2024

Related U.S. Application Data
(60) Provisional application No. 63/236,026, filed on Aug. 23, 2021.

(51) Int. Cl. H10F 19/30; H01L 25/04; H10F 19/40; H10F 77/122

(52) U.S. Cl. CPC H10F 19/30; H01L 25/043; H10F 19/40; H10F 77/122

(57) ABSTRACT

A system is provided. The system includes a thin film. The thin film includes a first material that absorbs light within a first band gap and passes a remaining portion of the light that is outside of the first band gap. The thin film is electrically connected to an intermediate electrical device. The thin film converts the light within the first band gap to electricity. The thin film provides the electricity to the intermediate electrical device. The system includes a solar panel that includes a second material that absorbs the remaining portion of the light passed by the thin film. The solar panel includes c-Si. The system includes a coupling between the solar panel and the thin film.

### CROSS REFERENCE TO RELATED APPLICATIONS

This application claims priority from U.S. Provisional Patent Application No. 63/236,026, entitled “RETROFITTING A THIN FILM TO A SOLAR SYSTEM,” filed on Aug. 23, 2021, which is hereby incorporated by reference as if set forth in full in this application for all purposes.

### FIELD OF INVENTION

The present invention is related to retrofitting a thin film to a solar system.

### BACKGROUND

Currently, there are no techniques for improving the electrical generation of a conventional solar cell once deployed. Practically, removing and replacing existing solar panels of the conventional solar system is the best and primary choice to capitalize on solar technology developments. There is a need for an alternative choice.

### SUMMARY

According to one or more embodiments, a system is provided. The system includes a thin film. The thin film includes a first material that absorbs light within a first band gap and passes a remaining portion of the light that is outside of the first band gap. The thin film is electrically connected to an intermediate electrical device. The thin film converts the light within the first band gap to electricity. The thin film provides the electricity to the intermediate electrical device. The system includes a solar panel that includes a second material that absorbs the remaining portion of the light passed by the thin film. The solar panel includes c-Si. The system includes a coupling between the solar panel and the thin film.

According to one or more embodiments, a method is provided. The method includes determining a deployment configuration of a plurality of panels of a solar array. At least one of the plurality of panels includes c-Si. The method includes retrofitting one or more thin films to the plurality of panels. Each of the one or more thin films includes a first material that absorbs light within a first band gap and passes a remaining portion of the light that is outside of the first band gap to the plurality of panels. The method includes drawing electricity from the one or more thin films to an intermediate electrical device according to the deployment configuration of the plurality of panels of the solar array. The above method can be implemented as a system, an apparatus, and/or other article of manufacture.

### BRIEF DESCRIPTION OF THE DRAWINGS

A more detailed understanding may be had from the following description, given by way of example in conjunction with the accompanying drawings, wherein like reference numerals in the figures indicate like elements, and wherein:

FIG. 1 illustrates a system and a graph according to one or more embodiments;

FIG. 2 illustrates an environment according to one or more embodiments;

FIG. 3 illustrates diagrams of a thin film roll according to one or more embodiments;

FIG. 4 illustrates a wiring design according to one or more embodiments;

FIG. 5 illustrates a wiring design according to one or more embodiments;

FIG. 6 illustrates a wiring design according to one or more embodiments;

FIG. 7 illustrates a wiring design according to one or more embodiments;

FIG. 8 illustrates a wiring design according to one or more embodiments;

FIG. 9 illustrates a method according to one or more embodiments;

FIG. 10 illustrates diagrams of applying a thin film to a solar panel according to one or more embodiments;

FIG. 11 illustrates a diagram of applying a thin film to a solar panel according to one or more embodiments;

FIG. 12 illustrates diagrams of applying a thin film to a solar panel according to one or more embodiments;

FIG. 13 illustrates diagrams of applying a thin film to a solar panel according to one or more embodiments;

FIG. 14 illustrates diagrams of applying a thin film to a solar panel according to one or more embodiments;

FIG. 15 illustrates diagrams of applying a thin film to a solar panel according to one or more embodiments;

FIG. 16 illustrates a diagram of applying a thin film to a solar panel according to one or more embodiments; and

FIG. 17 illustrates an example computing system according to one or more embodiments.

### DETAILED DESCRIPTION

Disclosed herein is a systems, methods, and apparatuses related to retrofitting one or more thin films to one or more solar panels of a solar system. More particularly, systems, methods, and apparatuses herein relate to retrofitting installed solar panels with semi-transparent or transmissive thin film solar panels.

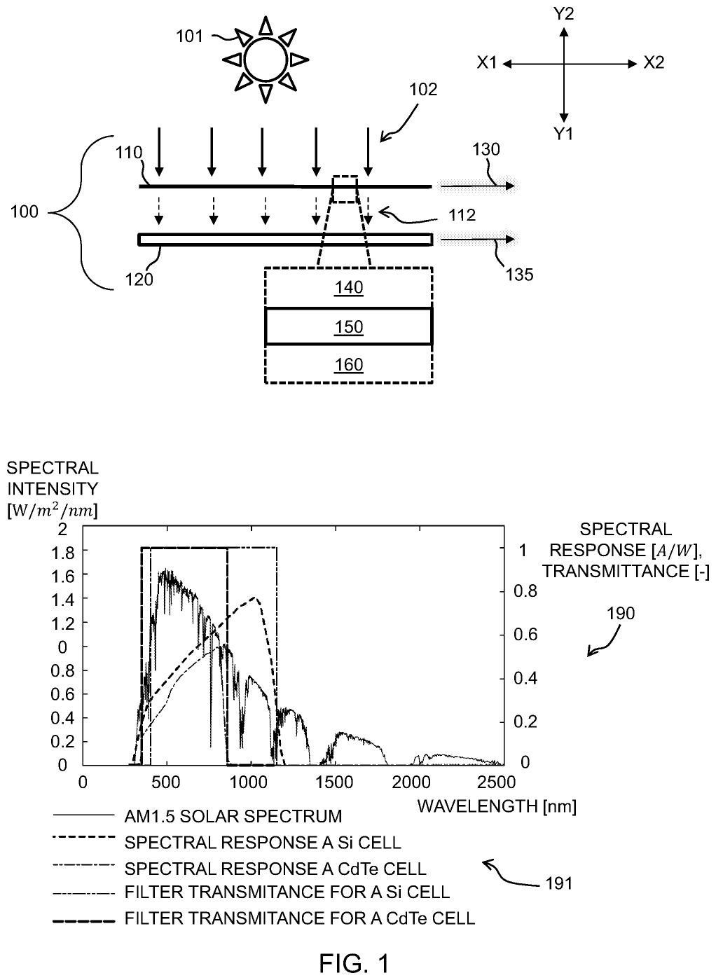

FIG. 1 illustrates a system 100 according to one or more embodiments. The system 100 receives, from a sun 101, light 102. The system 100 of FIG. 1 is oriented according to an X1-X2 axis (e.g., generally horizontal as oriented in the Figures, with the axis having a direction between left and right as in FIG. 1) and a Y1-Y2 axis (e.g., generally vertically as oriented in the Figures, with the axis having a direction between down and up as in FIG. 1). The X1 direction is opposite the X2 direction, and the Y1 direction is opposite the Y2 direction. Other orientations can be made in accordance with the X1-X2 and Y1-Y2 axes, which may be tilted or angled. Reference to a left side or left facing surface of a component described may be referred to as an X1 side or an X1 surface of the component, while reference to a right side or right facing surface of a component described may be referred to as an X2 side or an X2 surface of the component. Similarly, reference to a lower or bottom side or a downwardly facing surface of a component described may be referred to as a Y1 side or a Y1 surface, while reference to a top or upper side or upwardly facing surface of a component described may be referred to as a Y2 side or a Y2 surface.

As shown in FIG. 1, a thin film 110 of the system 100 first receives the light 102 from the sun 101 (e.g., solar irradiation) on a Y2 surface. The light 102 can be considered incident light or natural light and/or can also be sourced from an object other than the sun 101. The light 102 can range across the light spectrum including, but not limited to, ultraviolet (UV) light, visible light, and infrared light. The thin film 110 absorbs a portion of the light 102 (e.g., a first material convert the light 102 within a first band gap). The thin film 110 passes a remaining portion 112 of the light 102 in the Y1 direction to a solar panel 120. The solar panel 120 further absorbs the remaining portion 112 of the light 102 (e.g., a second material converts the light 102 that remains). In this way, the system 100 illustrates an example of transparency, transmission, and transformation of the light 102 from the sun 101 by the thin film 110 and the solar panel 120 into electricity 130.

The thin film 110, by way of example, can be a thin film solar panel, a thin film semi-transparent or transmissive solar panel, and/or a tandem solar module including one or more layers. The one or more layers of the thin film 110 can include but are not limited to a front layer 140, an absorbing layer 150, and a back layer 160, oriented from a Y2-Y1 direction. The front layer 140, which is on a Y2 side of the absorbing layer 150, can be a semi-transparent or transmissive conducting film, such as glass or the like, that allows incident light (e.g., the light 102) to reach the absorbing layer 150. The absorbing layer 150 can be a photoactive layer that converts solar irradiation energy (which is an example of the light 102) to electrical energy (e.g., the electricity 130). The absorbing layer 150 can include, but is not limited to, cadmium telluride (CdTe), amorphous silicon (a-Si), organic photovoltaic (OPV), and copper indium gallium selenide (CIGS), as well as other additives such as sulfur. In this way, the thin film 110 includes materials with a higher band gap than crystalline silicon (c-Si) of conventional solar systems, to increase the overall efficiency and power output of the system 100. The back layer 160, which is on a Y1 side of the absorbing layer 150, can be another electrode that completes a junction that enables power generation of the absorbing layer 150. The back layer 160 can pass any solar irradiation (e.g., the remaining portion 112) that is not absorbed by the absorbing layer 150, so that this solar irradiation reaches the solar panel 120.

According to one or more embodiments, regarding transparency, transmission, and transformation of and by the system 100, the system 100 adds to the overall power generation because the thin film 110 (e.g., a top tier) permits wavelengths that are longer than those in an absorption spectrum thereof (e.g., which is a function of a band gap of the thin film 110) to pass through and to the solar panel 120 (e.g., any material below or a next tier). For instance, based on a band gap of c-Si (1.11 eV), wavelengths in the orange and red visible region, as well as the near infrared region, should pass through the thin film 110 to the solar panel 120, such that the c-Si of the solar panel 120 receive energy to convert to the electricity 130. By way of example, CdTe, a-Si, OPV, and CIGS include band gaps greater than c-Si. Turning graph 190, an example spectral response of CdTe (e.g., the thin film 110) and c-Si (e.g., the solar panel 120) is shown. FIG. 1 also includes a key 191 identifying lines within the graph 190. The graph 190 includes an x-axis showing a nanometer scale for wavelength, as well as a left y-axis showing a spectral intensity and a right y-axis showing spectral response, transmittance. Note that the approximate absorption range for the CdTe is 400 to 800 nanometers (e.g., the second bandwidth). For example, in the system 100, the thin film 110 absorbs irradiance of the light 102 in the 190 to 800 nanometer wavelength range and passes unabsorbed light energy in the wavelength range greater than 800 nanometers.

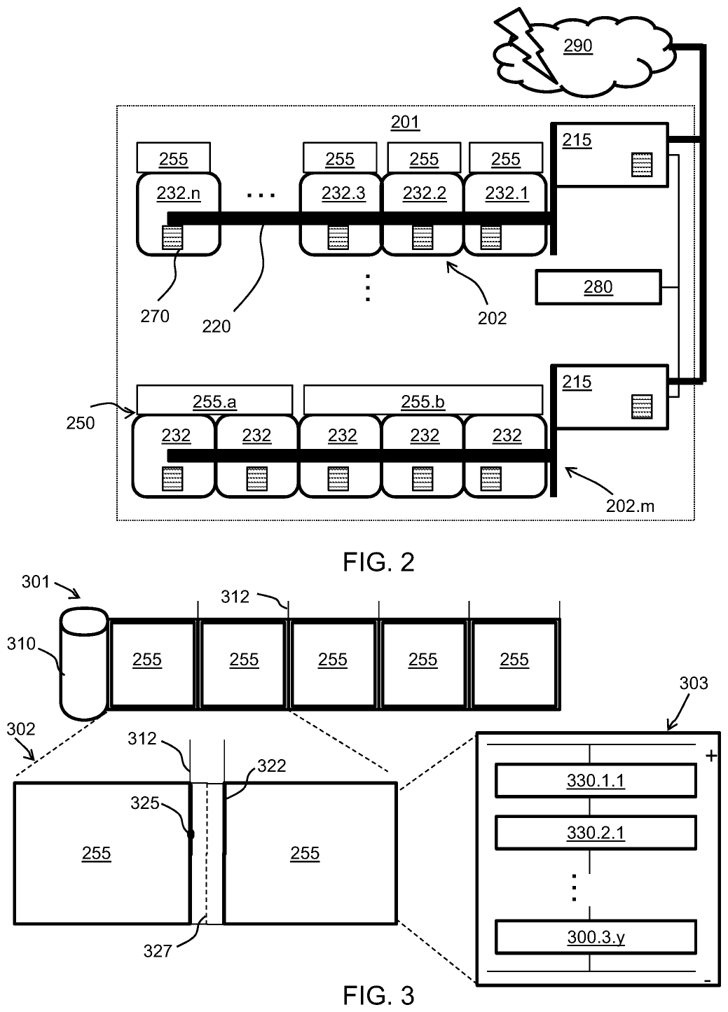

Turning now to FIG. 2, an environment 200 is illustrated according to one or more embodiments. The environment 200 can include one or more modular solar systems (e.g., the system 100) as discussed herein. Further, embodiments of the environment 200 include apparatuses, systems, methods, and/or computer program products at any possible technical detail level of integration. The environment 200 can be representative of the solar system located within a field 201 and including one or more solar arrays 202 (where m is an integer). The field 201 can be any expanse of open or cleared ground for supporting the one or more solar arrays 202, as well as rooftops and/or other property areas.

By way of example, a solar array 202 includes at least one combiner 215, one or more strings 220, and one or more panels 232 (where n is an integer). The combiner 215 can be any power electronic device or circuitry that changes between currents, such as direct current (DC) to alternating current (AC). The string 220 can be any electronic configuration that connects one or more electrical components (e.g., one or more panels 232), whether in series or in parallel to a particular electrical component (e.g., such as the combiner 215).

Each panel 232 can be an example of the solar panel 120 of FIG. 1. Each panel 232 is connected to a corresponding string 220 (e.g., via a pin connection, a pig tail connection, or the like), is joined by a coupling 250 (e.g., retrofitted) to a thin film 255, and can have at least one sensor 270. The coupling 250 can be a mechanical coupling such that the thin film 255 is in direct contact with the panel 232 and additional housing or like structures are omitted. A sensor 270 can be any transducer for converting conditions of the environment 200 to electrical signals. Further, additional sensor 270 can be located through the environment 200, such as on the combiners 215. The environment 200 and elements therein (e.g., any of the sensors 270) can be managed a device 280, such as by software as described herein, and can provide power/electricity a grid 290 or other load (e.g., one or more batteries).

Each thin film 255 can be an example of the thin film 110 of FIG. 1. The thin film 255 can be sized and or matched according to one or more configurations. Any and all size ratios for the thin film 255 are contemplated, whether fractionally or directly proportional to the panel 232 or the solar array 202 (e.g., the thin film 255 can match the length of the solar array 202).

Turning to FIG. 3, diagrams 301, 302, 303 are shown according to one or more embodiments. Diagram 301 illustrates a thin film roll 310 including the thin films 255 made in flexible sheets and provided with electrical contacts 312 (e.g. connectors, wires, or the like) therebetween. According to one or more embodiments, the flexible sheets can comprise polyethylene terephthalate. Further, due to the flexible and thin nature of the thin films 255 (i.e., nature of the thin films 110). Furthermore, the thin film roll 310 can maximize efficiency with respect to shipping and packaging by being a compact configuration suitable for on-site manipulation. Note that a width of the thin film roll 310 can match a width of the panel 232 and/or the solar array 202. Note also that the thin films 255 can be separated or cut at length, and contacts, connections, or the like can be applied to each thin film 255 in the field.

Diagram 302 illustrates a closer view of two thin films 255 of the thin film roll 310 with the connections 312 and contact strips 322 (e.g., both representing the electrical contacts 420) embedded therein for each thin film 255. The connections 312 and contact strips 322 can be any conductive material used to transfer electricity, such as wires, pins, receptacles, and the like. The thin films 225 can also include one or more vias 325 for applying the contacts and connections (or the like). These two thin films 255 can be connected by a seam 327 (e.g., perforated to allow for easy separation in the field 201). In this way, each the thin film 255 can be separated or cut from the thin film roll 310.

Diagram 303 includes one or more cells 330 arranged in an x-y grid, where x is 1 and y is an integer greater than 0, of the thin film 255. The one or more cells 330 can be arranged in the x-y grid, where both x and y are integers greater than 0. The width, wiring, configuration of cells 330 can be managed and operated to control power generation on a per cell basis. The location and wiring of each cell can be matched to the panel 232 to maximize transmissivity (e.g., reduce shadows).

Accordingly, as shown in FIG. 2, the thin film 255 can have a one to one ratio to the panel 232. The thin film 255.a can also have a one to two ratio to the panel 233, and the thin film 255.b can also have a one to three ratio to the panel 232. In some cases, the thin film 255 can cover the entire solar array 202 from end to end.

Generally, a tandem configuration can be a wired with a 2-terminal configuration that requires voltage matching. This means that if one panel 232 produces more energy than another 232, less of that energy is used, which results in a lower overall efficiency. According to one or more embodiments, to address any electrical aggregation challenges, the one or more thin films 255 can be aggregated separately at the combiner box 215.

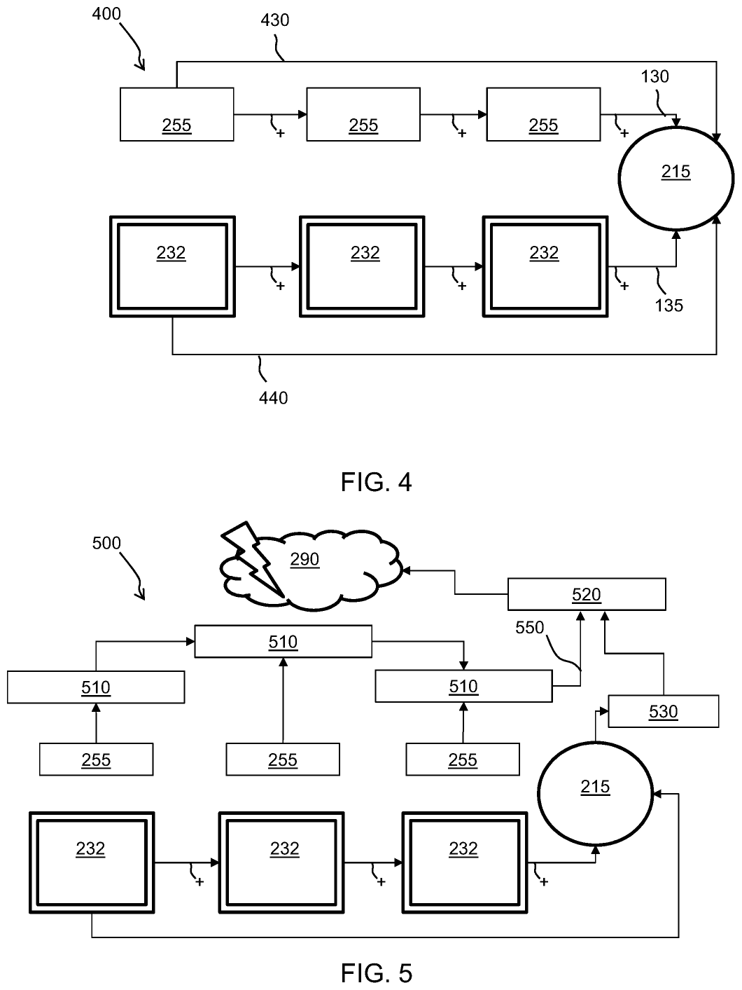

Turning to FIG. 4, a wiring design 400 is shown according to one or more embodiments. For brevity, elements of FIG. 4 that are similar to elements of FIGS. 1-3 are reused. According to one or more embodiments, for the wiring design 400, one or more thin films 255 are serially linked to the combiner box 215 with a ground 430 to produce electricity 130 and one or more panels 232 are serially linked (e.g., the silicon panels are in series) to the combiner box 215 with a ground 440 to produce electricity 135. In an example, the one or more thin films 255 and the one or more panels 232 are in a 4-terminal configuration in which the two solar panels 232 are in parallel for the entire solar array (e.g., the solar array 202) and get aggregated at the end of a string (e.g., the solar array 220). Therefore, separate electrical contacts and connections (e.g., the connections 312 and contact strips 322) can be on the one or more thin films 255.

One or more wiring diagram embodiments are described with respect to FIGS. 5-8, with elements of FIGS. 5-8 that are similar to elements of FIGS. 1-4 being reused. Note that features and/or elements of any of the wiring diagrams described herein can be used alone or in any combination with the other features and elements. Turning to FIG. 5, a wiring design 500 is shown according to one or more embodiments. Further, the wiring design 500 shows an electrical setup using at least one intermediate electrical device 510. The at least one intermediate electrical device is configured to adjust, adapt, convert, and/or augment electricity generated by the thin film 255 so that the electricity is provided in a format combatable (e.g., current and voltage combatable) with electricity generated by the solar panels 232. Examples of the at least one intermediate electrical device 510 can include, but are not limited to microinverters and DC-DC optimizers.

For instance, as shown in FIG. 5, each thin film 255 can correspond to a separate intermediate electrical device 510, each of which is a microinverter. Each microinverter can convert DC power collected from the thin films 225 to AC power, thereby enabling AC connections direct (arrow 550) to a switchgear 520. The switchgear 250 can include electrical disconnect switches, fuses, and/or circuit breakers used to control, protect, and isolate elements of the wiring design 500. For example, the switchgear 520 can be used to de-energize equipment to allow work to be done and to clear faults downstream. Note that electricity from the one or more panels 232 goes through the combiner box 215 to the inverter 530, before continuing to the switchgear 540 and out to the grid 290.

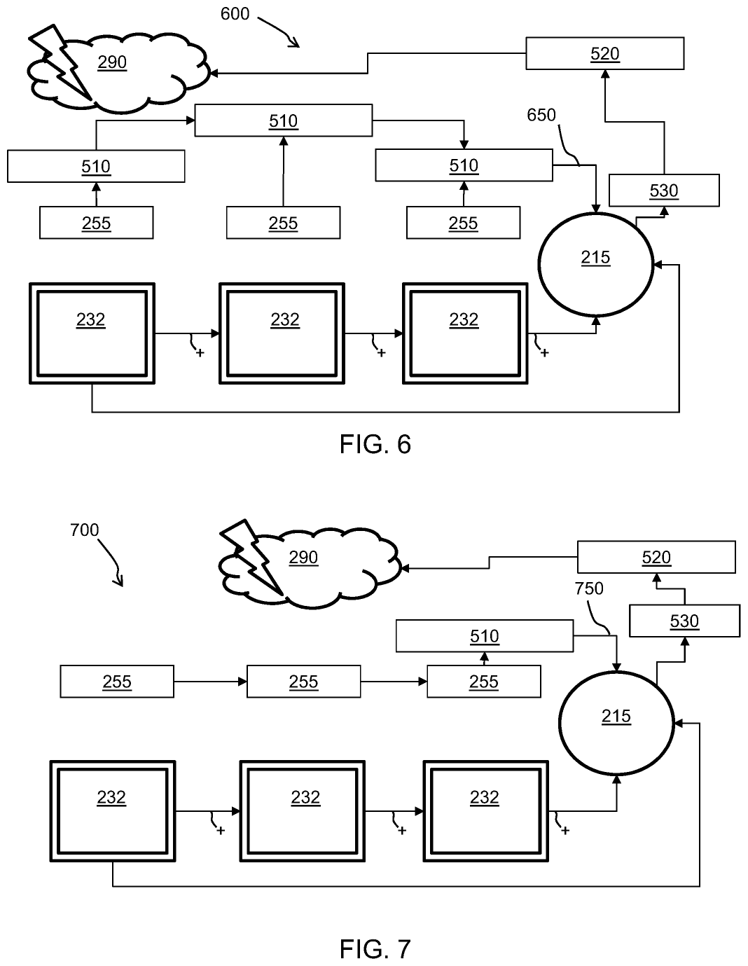

As shown in FIG. 6, a wiring design 600 is provided according to one or more embodiments. The wiring design 600 can be considered a panel level voltage mapping. Each thin film 255 can correspond to a separate intermediate electrical device 510, each of which is a panel level DC-DC optimizers. The panel level DC-DC optimizers lower the voltage and raise the current to match the voltage of the one or more panels 232. Generally, each DC-DC optimizer takes DC energy (i.e., from the thin film 255 and/or another DC-DC optimizer 610) and regulates and delivers (arrow 650) that DC energy to the combiner 215.

As shown in FIG. 7, a wiring design 700 is provided according to one or more embodiments. The wiring design 700 can be considered a string level voltage mapping. Each thin film 255 can be connected in series to a single intermediate electrical device 510, such as a single DC-DC optimizer that regulates and delivers (arrow 750) that DC energy to the combiner 215.

As shown in FIG. 8, a wiring design 800 is provided according to one or more embodiments. Each thin film 255 can be connected in series to a single intermediate electrical device 510, such as a microinverter that regulates and delivers (arrow 850) that DC energy to the combiner 215.

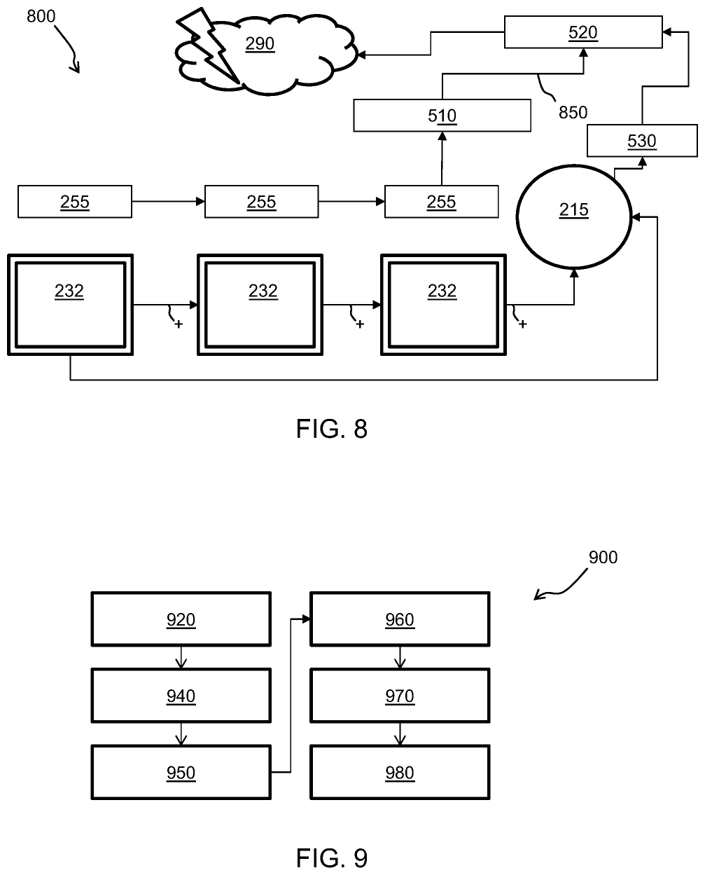

Turning now to FIG. 9, a method 900 is illustrated according to one or more embodiments. The method 900 provides a retrofitting operation example to enable a technician to build a solar system.

The method 900 includes block 920, where a determination is made with respect to a deployment configuration of the panels 232 of the solar array 202, as well as the cells therein. This determination can be made by software of a device 280 monitoring the solar array 202. This software can receive one or more inputs to make such a determination. The inputs can be data provided by the one or more sensors 270 and/or through other sources provided in real time or otherwise. According to one or more embodiments, the data can include one or more of temperature, current, light, motion, sound, solar irradiation, proximity, and/or position data, as well as historical data, data from other environments, data from other systems (e.g., weather data). The data can include a cell arrangement, such as described with respect to FIG. 3, such that the thin films 255 can match the panels 232 to maximize transmissivity. The determination can also be made by the technician.

At block 940, the one or more thin films 255 are retrofitted to the one or more solar panels 232. In this regard, retrofitted can include one or more of the thin films 255 being affixed, attached, glued, coupled, etc. by the technician or substitute to the one or more panels 232. According to one or more embodiments, the retrofitting of the one or more thin films 255 to the one or more solar panels 232 can be direct, such as in the absence of a housing or like structure.

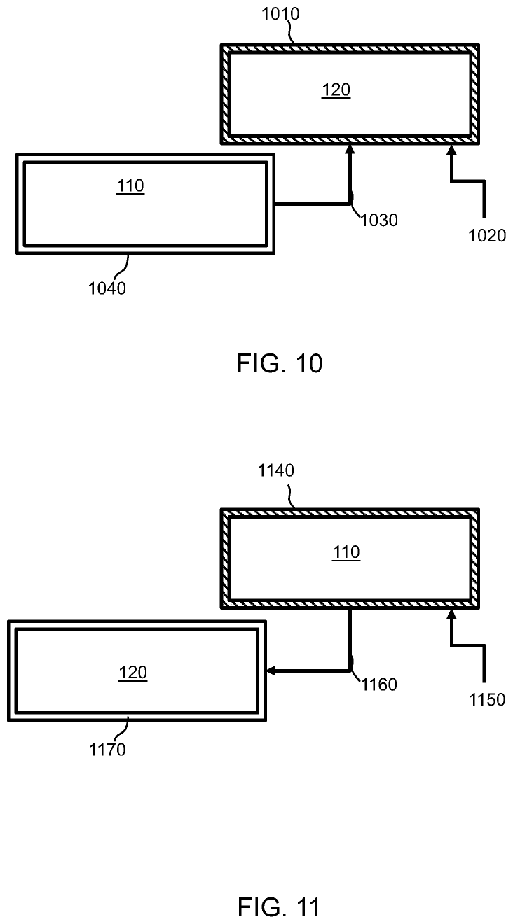

For example, once the one or more thin films 255 are selected and/or sized, the one or more thin films 255 can then be applied atop a surface of the one or more solar panels 232 (e.g., a Y2 surface). Accordingly, any existing panel 232 can be first cleaned and dried. Next, the thin film can be applied to the surface. Note that care is taken to ensure a clean and bubble free application of the one or more thin films 255, as well as the alignment of cells, to ensure ideal light transmission (i.e., maximum transmissivity). Examples of retrofitting are further described herein, such as with respect to FIGS. 10-16. For brevity, elements of FIGS. 10-16 that are similar to previously described elements are reused.

FIG. 10 illustrates a diagram of coupling the thin film 110 to the solar panel 120 according to one or more embodiments. As shown, a contact site 1010 of the solar panel 120 receives (represented by arrow 1020) an adhesive tape, double sided tape, a glue, and/or an adhesive material. The contact site 1010 can be an edge and/or a frame of the solar panel 120. Next, the thin film 110 is applied (represented by arrow 1030) onto the solar panel 120 so that the adhesive tape, double sided tape, a glue, and/or an adhesive material can interact with the thin film 110 and the solar panel 120 to secure the coupling 250 (e.g., a mechanical coupling). In one or more embodiments, the contact site 1010 of the solar panel 120 aligns with an edge and/or a frame 1040 of the thin film 110. Note that the thin film 110 to the solar panel 120 are directly coupled to avoid additional housing or like structures.

FIG. 11 illustrates a diagram of coupling the thin film 110 to the solar panel 120 according to one or more embodiments. As shown, a contact site 1140 of the thin film 110 receives (represented by arrow 1150) an adhesive tape, double sided tape, a glue, and/or an adhesive material. The contact site 1140 can be an edge and/or a frame of the thin film 110. Next, the thin film 110 is applied (represented by arrow 1010) onto the solar panel 120 so that the adhesive tape, double sided tape, a glue, and/or an adhesive material can interact with the thin film 110 and the solar panel 120 to secure the coupling 250 (e.g., a mechanical coupling). In one or more embodiments, the contact site 1110 of the thin film 110 aligns with an edge and/or a frame 1170 of the solar panel 120. Note that the thin film 110 to the solar panel 120 are directly coupled to avoid additional housing or like structures.

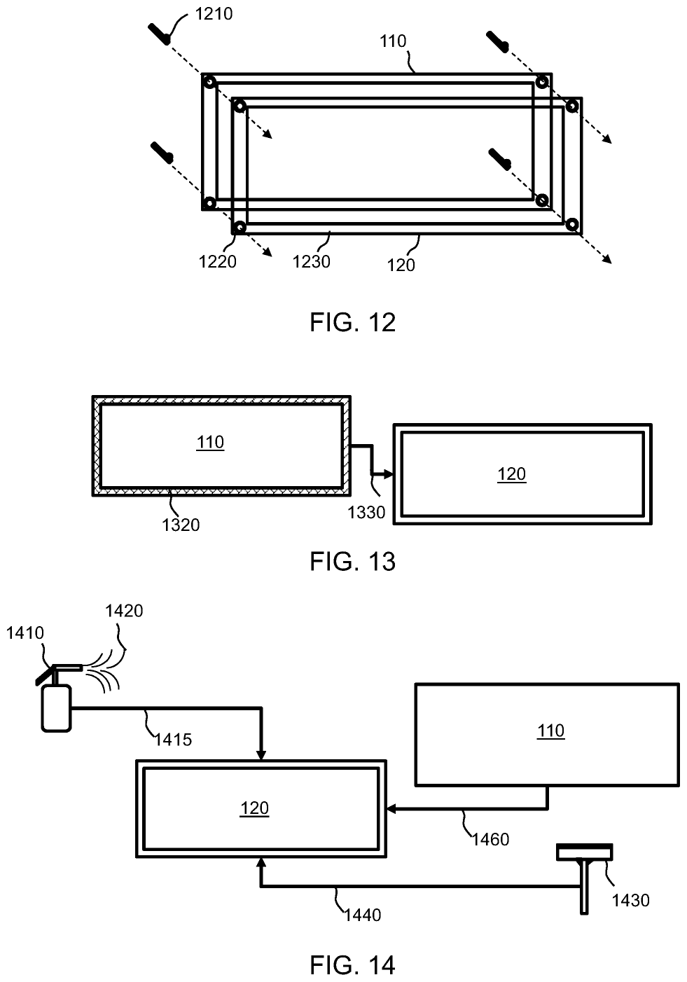

FIG. 12 illustrates a diagram of fastening the thin film 110 and the solar panel 120 together according to one or more embodiments. The diagram illustrates fastener 1210, which can wire formed pins with two prongs, screws, bolts, or the like. The fastener 1210 can be inserted into holes 1220 in the thin film 110 and the solar panel 120 to secure the coupling 250 (e.g., a mechanical coupling). Note that the thin film 110 and the solar panel 120 can include a frame 1230. The frame 1230 can be an outer boarder of the one or more layers of the thin film 110.

FIG. 13 illustrates a diagram of coupling the thin film 110 and the solar panel 120 according to one or more embodiments. Particularly, the thin film 110 can include an adhesive frame 1320. The adhesive frame 1320 can have a backing that when peeled off exposes an adhesive substance capable of securing the thin film 110 to the solar panel 120. Thus, once the backing is removed, the thin film 110 is applied (represented by arrow 1330) to the solar panel 120 to secure the coupling 250 (e.g., a mechanical coupling).

FIG. 14 illustrates a diagram of coupling the thin film 110 and the solar panel 120 according to one or more embodiments. The diagram depicts a spray applicator 1410. The spray applicator 1410 can be any device capable of spraying, distributing, and/or depositing (represented by arrow 1415) a solution 1420 onto the solar panel 120 (or the thin film 110). An example of the spray applicator 1410 includes, but is not limited to, a spray bottle. Next, using a squeegee 1430, the solution 1420 can be evenly applied or smoothed (represented by arrow 1440). Care should be taken to ensure a clean and bubble free application of the solution 1420 to ensure ideal light transmission between the thin film 110 and the solar panel 120. Then, the thin film 110 can be applied (represented by arrow 1460) onto the solar panel 120 to secure the coupling 250 (e.g., a mechanical coupling).

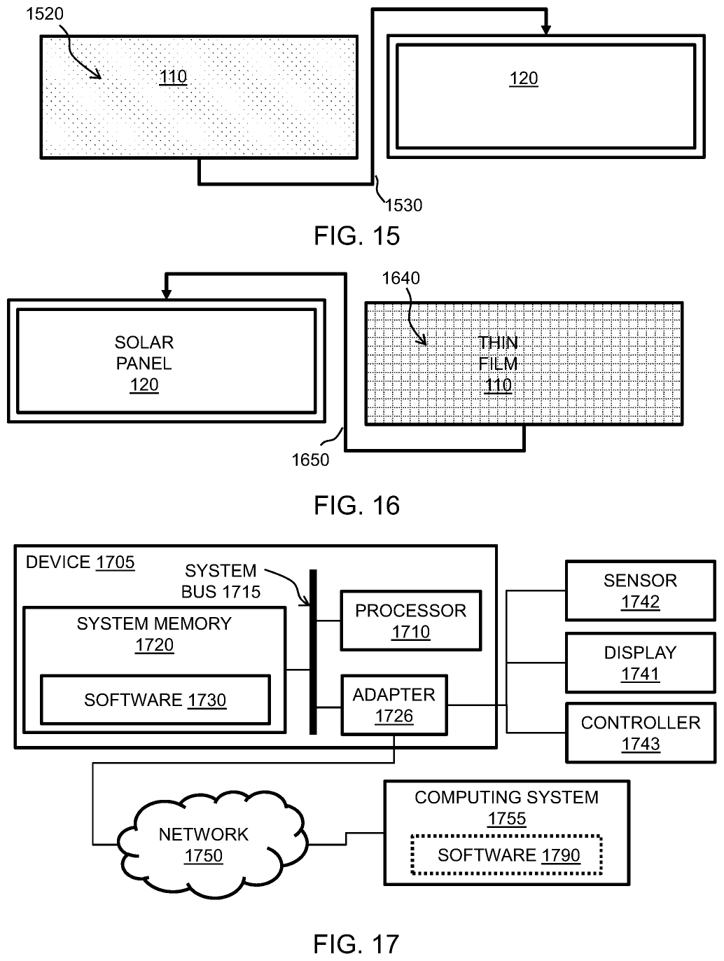

FIG. 15 illustrates a diagram of coupling the thin film 110 and the solar panel 120 according to one or more embodiments. The thin film 110 can include an adhesive film 1520 throughout, such as on an outer surface of the back layer 160 of FIG. 1. The adhesive film 1520 can have a backing that when peeled off exposes an adhesive substance capable of securing the thin film 110 to the solar panel 120. Thus, once the backing is removed, the thin film 110 is applied (represented by arrow 1530) to the solar panel 120 to secure the coupling 250 (e.g., a mechanical coupling). According to one or more embodiments, the adhesive film 1520 can be deposited with respect to any pattern, matrix, or the like, as well as be aligned with any non-transmissive space of the thin film 110.

FIG. 16 illustrates a diagram of coupling the thin film 110 and the solar panel 120 according to one or more embodiments. The thin film 110 can include an adhesive grid 1640, such as on an outer surface of the back layer 160 of FIG. 1. The adhesive grid 1640 can have a backing that when peeled off exposes an adhesive substance capable of securing the thin film 110 to the solar panel 120. Thus, once the backing is removed, the thin film 110 is applied (represented by arrow 1650) to the solar panel 120 to secure the coupling 250. According to one or more embodiments, the adhesive grid 1640 can be deposited with respect to any negative space of the solar panel 120 (e.g., non-photo sensitive space between semiconductors of the solar panel 120), as well as be aligned with any non-transmissive space of the thin film 110.

Returning to FIG. 9, the method 900 continues at block 950, where the one or more thin films 255 are electrically connected to one or more intermediate electrical devices 510. Further, at block 960, the one or more thin films 255 convert the light 102 within the first band gap to the electricity 130. In this regard, the one or more thin films 255 include a first material, like CdTe as described herein, to convert the light 102 within the first band gap.

At block 970, the electricity 135 from the one or more solar panels 232 can be aggregated. At block 980, the electricity 130 from the one or more thin films 255 can be drawn (e.g., the one or more thin films 255 provides that electricity 130 to the intermediate electrical device 510) according to the deployment configuration of the one or more solar panels 232 as determined in block 920. Examples of wiring designs can be found discussed herein, such as shown in FIGS. 4-8.

FIG. 17 illustrates an example computing system (e.g., the device 280 of FIG. 2) according to one or more embodiments. The computing system can be representative of any computing device, computing apparatus, and/or computing environment, which comprise hardware, software, or a combination thereof. Further, embodiments of the computing system disclosed may include apparatuses, systems, methods, and/or computer program products at any possible technical detail level of integration.

The computing system has a device 1705 (e.g., the device 280 of FIG. 2) with one or more central processing units (CPU(s)), which are collectively or generically referred to as a processor 1710. The processor 1710, also referred to as processing circuits, is coupled via a system bus 1715 to a system memory 1720 and various other components. The computing system and/or the device 1705 may be adapted or configured to perform as an online platform, a server, an embedded computing system, a personal computer, a console, a personal digital assistant (PDA), a cell phone, a tablet computing device, a quantum computing device, cloud computing device, a mobile device, a smartphone, a fixed mobile device, a smart display, a wearable computer, or the like.

The processor 1710 may be any type of general or specific purpose processor, including a central processing unit (CPU), application specific integrated circuit (ASIC), field programmable gate array (FPGA), graphics processing unit (GPU), controller, multi-core processing unit, three dimensional processor, quantum computing device, or any combination thereof. The processor 1710 may also have multiple processing cores, and at least some of the cores may be configured to perform specific functions. Multi-parallel processing may also be configured. In addition, at least the processor 1710 may be a neuromorphic circuit that includes processing elements that mimic biological neurons.

The bus 1715 (or other communication mechanism) is configured for communicating information or data to the processor 1710, the system memory 1720, and various other components, such as the adapter 1726.

The system memory 1720 is an example of a (non-transitory) computer readable storage medium, where software 1730 can be stored as software components, modules, engines, instructions, or the like for execution by the processor 1710 to cause the device 1705 to operate, such as described herein with reference to FIG. 1. The system memory 1720 can include any combination of a read only memory (ROM), a random access memory (RAM), internal or external Flash memory, embedded static-RAM (SRAM), solid-state memory, cache, static storage such as a magnetic or optical disk, or any other types of volatile or non-volatile memory. Non-transitory computer readable storage mediums may be any media that can be accessed by the processor 1710 and may include volatile media, non-volatile media, or the like. For example, the ROM is coupled to the system bus 1715 and may include a basic input/output system (BIOS), which controls certain basic functions of the device 1705, and the RAM is read-write memory coupled to the system bus 1715 for use by the processors 1710. Non-transitory computer readable storage mediums can include any media that is removable, non-removable, or the like.

According to one or more embodiments, the software 1730 can be configured in hardware, software, or a hybrid implementation. The software 1730 can be composed of modules that are in operative communication with one another, and to pass information or instructions. According to one or more embodiments, the software 1730 can provide one or more user interfaces, such as on behalf of the operating system or other application and/or directly as needed. The user interfaces include, but are not limited to, graphic user interfaces, window interfaces, internet browsers, and/or other visual interfaces for applications, operating systems, file folders, and the like. Thus, user activity can include any interaction or manipulation of the user interfaces provided by the software 1730. The software 1730 can further include custom modules to perform application specific processes or derivatives thereof, such that the computing system may include additional functionality. For example, according to one or more embodiments, the software 1730 may be configured to store information, instructions, commands, or data to be executed or processed by the processor 1710 to logically implement the methods described herein (e.g., big data operations with respect to machine learning and artificial intelligence). The software 1730 of FIG. 17 can also be representative of an operating system, a mobile application, a client application, and/or the like for the device 1705 for the computing system.

Further, modules of the software 1730 can be implemented as a hardware circuit comprising custom very large scale integration (VLSI) circuits or gate arrays, off-the-shelf semiconductors such as logic chips, transistors, or other discrete components, in programmable hardware devices (e.g., field programmable gate arrays, programmable array logic, programmable logic devices), graphics processing units, or the like. Modules of the software 1730 can be at least partially implemented in software for execution by various types of processors. According to one or more embodiments, an identified unit of executable code may include one or more physical or logical blocks of computer instructions that may, for instance, be organized as an object, procedure, routine, subroutine, or function. Executables of an identified module co-located or stored in different locations such that, when joined logically together, comprise the module. A module of executable code may be a single instruction, one or more data structures, one or more data sets, a plurality of instructions, or the like distributed over several different code segments, among different programs, across several memory devices, or the like. Operational or functional data may be identified and illustrated herein within modules of the software 1730, and may be embodied in a suitable form and organized within any suitable type of data structure.

Furthermore, modules of the software 1730 can also include, but are not limited to, location modules, augmented reality modules, virtual reality modules, blockchain module, and machine learning and/or an artificial intelligence (ML/AI) algorithm modules. In an example, modules of the software 1730 can modulate signaling onto power wires for inter-panel communication and/or provide wireless communication.

A location module can be configured can be configured to create, build, store, and provide algorithms and models that determine a location of the device 1705 and relative distances. According to more or more embodiments, the location module can implement location, geosocial networking, spatial navigation, satellite orientation, surveying, distance, direction, and/or time software.

An augmented reality module can be configured to create, build, store, and provide algorithms and models that provide interactive experiences of a real-world environments where objects that reside in the real world are enhanced by computer-generated perceptual information, sometimes across multiple sensory modalities. A virtual reality module can be configured to create, build, store, and provide algorithms and models that simulate experiences similar to or completely different from the real world. According to more or more embodiments, the virtual reality and/or the augmented reality modules can provide augmented, mixed, immersive, and/or text-based virtual reality.

A blockchain module can be configured to create, build, store, and provide algorithms and models that provide records or blocks linked together using cryptography, such that each block contains at least one or more of a cryptographic hash of the previous block (e.g., thereby forming a chain), a timestamp, and transaction data (e.g., social data, connection data, preference data, etc.). The timestamp can identify that the transaction data existed when the block was published to get into its hash.

A ML/AI algorithm module can be configured to create, build, store, and provide algorithms and models that improve automatically through experience, as well as emulate ‘natural’ cognitive abilities of humans. In an example, machine learning software uses training data to build a particular model and to improve that model, while artificial intelligence software perceives an environment (e.g., receives active data) and takes actions (e.g., applies a model) to solve a problem and/or produce an output. Artificial intelligence software can use a model built by humans and/or machine learning software. Artificial intelligence software can further provide feedback to the machine learning software to improve any models thereof. Machine learning and artificial intelligence can exist independently and/or coexist.

The adapter 1726 of FIG. 17 can be representative of one or more adapters. For example, the device 1705 can particularly include an input/output (I/O) adapter, a device adapter, and a communications adapter. According to one or more embodiments, the I/O adapter can be configured as a small computer system interface (SCSI), of in view of frequency division multiple access (FDMA) single carrier FDMA (SC-FDMA), time division multiple access (TDMA), code division multiple access (CDMA), orthogonal frequency-division multiplexing (OFDM), orthogonal frequency-division multiple access (OFDMA), global system for mobile (GSM) communications, general packet radio service (GPRS), universal mobile telecommunications system (UMTS), cdma2000, wideband CDMA (W-CDMA), high-speed downlink packet access (HSDPA), high-speed uplink packet access (HSUPA), high-speed packet access (HSPA), long term evolution (LTE), LTE Advanced (LTE-A), 802.11x, Wi-Fi, Zigbee, Ultra-WideBand (UWB), 802.16x, 802.15, home Node-B (HnB), Bluetooth, radio frequency identification (RFID), infrared data association (IrDA), near-field communications (NFC), fifth generation (5G), new radio (NR), or any other wireless or wired device/transceiver for communication. The device adapter interconnects input/output devices to the system bus 1715, such as a display 1741, a sensor 1742, a controller 1743, or the like (e.g., a camera, a speaker, etc.).

The communications adapter interconnects the system bus 1715 with a network 1750, which may be an outside network, enabling the device 1705 to communicate data with other such devices (e.g., such a computing system 1755 through the network 1750). In one embodiment, the adapter 1726 may be connected to one or more I/O buses that are connected to the system bus 1715 via an intermediate bus bridge. Suitable I/O buses for connecting peripheral devices such as hard disk controllers, network adapters, and graphics adapters typically include common protocols, such as the Peripheral Component Interconnect (PCI).

The display 1741 is configured to provide one or more UIs or graphic UIs (GUIs) that can be captured by and analyzes by the software 1730, as the users interacts with the device 1705. Examples of the display 1741 can include, but are not limited to, a plasma, a liquid crystal display (LCD), a light emitting diode (LED), a field emission display (FED), an organic light emitting diode (OLED) display, a flexible OLED display, a flexible substrate display, a projection display, a 4K display, a high definition (HD) display, a Retina© display, an in-plane switching (IPS) display or the like. The display 1741 may be configured as a touch, three dimensional (3D) touch, multi-input touch, or multi-touch display using resistive, capacitive, surface-acoustic wave (SAW) capacitive, infrared, optical imaging, dispersive signal technology, acoustic pulse recognition, frustrated total internal reflection, or the like as understood by one of ordinary skill in the art for input/output (I/O).

The sensor 1742, such as any transducer configured to convert one or more environmental conditions into an electrical signal, may be further coupled to the system bus 1715 for input to the device 1705. In addition, one or more inputs may be provided to the computing system remotely via another computing system (e.g., the computing system 1755) in communication therewith, or the device 1705 may operate autonomously. For example, the sensor 1742 can include one or more of an electrode, a temperature sensor (e.g., thermocouple), a current sensor, a photosensor, an accelerometer, a microphone, a solar irradiation sensor, a proximity sensor, position sensor, and a long range (LoRa) sensor (e.g., any low-power wide-area network modulation sensor).

According to one or more embodiments, the sensors 1742 can be installed at each level and integrated into an environment (e.g., the environment 200 of FIG. 2) to monitor operations therein, such as identify when a specific solar panel is not functioning correctly. For example. when a panel's electric current falls below a defined threshold, the sensors 1742 (e.g., electric current sensors) send a signal to the software 1730 to identify a malfunctioning module's exact location. Each sensor 1742 comprises a serial number that can be matched with each panel/cartridge/truss/etc. (e.g., as identified on a scannable code) and corresponding level of the environment (e.g., the environment 200 of FIG. 2).

The controller 1743, such as a computer mouse, a touchpad, a touch screen, a keyboard, a keypad, or the like, may be further coupled to the system bus 1715 for input to the device 1705. In addition, one or more inputs may be provided to the computing system remotely via another computing system (e.g., the computing system 1755) in communication therewith, or the device 1705 may operate autonomously. The controller 1743 can also be representative of one or more actuators or the like for moving, locking, unlocking portions of the environment (e.g., the environment 200 of FIG. 2).

According to one or more embodiments, the functionality of the device 1705 with respect to the software 1730 can also be implemented on the computing system 1755, as represented by separate instances of the software 1790. Note that the software 1790 can be stored in a common repository located at the device 1705 and/or the computing system 1755 and can be downloaded (on demand) to and/or from each of the device 1705 and/or the computing system 1755. According to one or more embodiments, a system is provided. The system includes a thin film. The thin film includes a first material that absorbs light within a first band gap and passes a remaining portion of the light that is outside of the first band gap. The thin film is electrically connected to an intermediate electrical device. The thin film converts the light within the first band gap to electricity. The thin film provides the electricity to the intermediate electrical device. The system includes a solar panel that includes a second material that absorbs the remaining portion of the light passed by the thin film. The solar panel includes c-Si. The system includes a coupling between the solar panel and the thin film.

According to one or more embodiments or any of the system embodiments herein, the intermediate electrical device can adjust, adapt, convert, or augment the electricity generated by the thin film to a current and voltage combatable with electricity generated by the solar panel.

According to one or more embodiments or any of the system embodiments herein, the thin film and the solar panel can be directly coupled to avoid a housing structure.

According to one or more embodiments or any of the system embodiments herein, the thin film can include CdTe, a-Si, OPV, or CIGS.

According to one or more embodiments or any of the system embodiments herein, the thin film can include a front layer, an absorbing layer, and a back layer.

According to one or more embodiments or any of the system embodiments herein, the front layer can include a transmissive conducting film that allows incident light to the system to pass through to the absorbing layer.

According to one or more embodiments or any of the system embodiments herein, the absorbing layer can include a photoactive layer that converts the light within the first band gap to the electricity.

According to one or more embodiments or any of the system embodiments herein, the layer can include an electrode that completes a junction that enables the electricity generation by the absorbing layer.

According to one or more embodiments or any of the system embodiments herein, the coupling can include a mechanical coupling by one or more fasteners.

According to one or more embodiments or any of the system embodiments herein, the coupling can include a mechanical coupling by an adhesive material on an edge portion of the solar panel or the thin film.

According to one or more embodiments or any of the system embodiments herein, the coupling can include a mechanical coupling by an adhesive film.

According to one or more embodiments, a method is provided. The method includes determining a deployment configuration of a plurality of panels of a solar array. At least one of the plurality of panels includes c-Si. The method includes retrofitting one or more thin films to the plurality of panels. Each of the one or more thin films includes a first material that absorbs light within a first band gap and passes a remaining portion of the light that is outside of the first band gap to the plurality of panels. The method includes drawing electricity from the one or more thin films to an intermediate electrical device according to the deployment configuration of the plurality of panels of the solar array.

According to one or more embodiments or any of the method embodiments herein, the one or more thin films can generate the electricity by converting the light within the first band gap.

According to one or more embodiments or any of the method embodiments herein, the one or more thin films can electricity connect to the intermediate electrical device.

According to one or more embodiments or any of the method embodiments herein, the retrofitting of the one or more thin films to the plurality of panels can include a direct and mechanical coupling configured to avoid a housing structure.

According to one or more embodiments or any of the method embodiments herein, the intermediate electrical device can adjust, adapt, convert, or augment the electricity generated by the one or more thin films to a current and voltage combatable with electricity generated by the plurality of panels.

According to one or more embodiments or any of the method embodiments herein, at least one of the one or more thin films can be CdTe, a-Si, OPV, or CIGS.

According to one or more embodiments or any of the method embodiments herein, the one or more thin films can include a front layer, an absorbing layer, and a back layer.

According to one or more embodiments or any of the method embodiments herein, the absorbing layer can include a photoactive layer that converts the light within the first band gap to the electricity.

According to one or more embodiments or any of the method embodiments herein, the back layer can include an electrode that completes a junction that enables the electricity generation by the absorbing layer.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. A computer readable medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire

Examples of computer-readable media include electrical signals (transmitted over wired or wireless connections) and computer-readable storage media. Examples of computer-readable storage media include, but are not limited to, a register, cache memory, semiconductor memory devices, magnetic media such as internal hard disks and removable disks, magneto-optical media, optical media such as compact disks (CD) and digital versatile disks (DVDs), a random access memory (RAM), a read-only memory (ROM), an erasable programmable read-only memory (EPROM or Flash memory), a static random access memory (SRAM), and a memory stick. A processor in association with software may be used to implement a radio frequency transceiver for use in a terminal, base station, or any host computer.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The descriptions of the various embodiments herein have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A system comprising:
a thin film comprising a first material that absorbs light within a first band gap and transmits a remaining portion of the light, the first material comprising a cadmium (Cd) alloy, the thin film being electrically connected to an intermediate electrical device, the thin film converting the light within the first band gap to a first electricity, and the thin film providing the first electricity to the intermediate electrical device;
a solar panel comprising a second material that absorbs the remaining portion of the light transmitted by the thin film, the solar panel comprising crystalline silicon (c-Si) and being electrically distinct from the thin film, the solar panel converting the remaining portion of the light (102) to a second electricity; and
a mechanical coupling between the solar panel and the thin film.

2. The system of claim 1, wherein the intermediate electrical device adjusts, adapts, converts, or augments the first electricity generated by the thin film to a current and voltage combatable with the second electricity generated by the solar panel.

3. The system of claim 1, wherein the thin film and the solar panel are directly coupled to avoid a housing structure.

4. The system of claim 1, wherein the thin film comprises cadmium telluride (CdTe), amorphous silicon (a-Si), organic photovoltaic (OPV), or copper indium gallium selenide (CIGS).

5. The system of claim 1, wherein the thin film comprises a front layer, an absorbing layer, and a back layer.

6. The system of claim 5, wherein the front layer comprises a transmissive conducting film that allows incident light to the system to pass through to the absorbing layer.

7. The system of claim 5, wherein the absorbing layer comprises a photoactive layer that converts the light within the first band gap to the first electricity, and the photoactive layer comprises the cadmium (Cd) alloy.

8. The system of claim 5, wherein the back layer comprises an electrode that completes a junction that enables generation of the first_electricity by the absorbing layer.

9. The system of claim 1, wherein the mechanical coupling is implemented by one or more fasteners.

10. The system of claim 1, wherein the mechanical coupling is implemented by an adhesive material on an edge portion of the solar panel or the thin film.

11. The system of claim 1, wherein the mechanical coupling is implemented by an adhesive film.

12. A method comprising:
determining a deployment configuration of a plurality of panels of a solar array, at least one of the plurality of panels comprising crystalline silicon (c-Si);
retrofitting one or more thin films to the plurality of panels via a direct and mechanical coupling, each of the one or more thin films comprising a first material that absorbs light within a first band gap and transmits a remaining portion of the light to the plurality of panels, the first material comprising a cadmium (Cd) alloy, and the one or more thin films being electrically distinct from the plurality of panels; and
drawing a first_electricity from the one or more thin films to an intermediate electrical device according to the deployment configuration of the plurality of panels of the solar array and drawing a second electricity from the solar panel that is converting the remaining portion of the light.

13. The method of claim 12, wherein the one or more thin films generate the first electricity by converting the light within the first band gap.

14. The method of claim 12, wherein the one or more thin films are electricity connected to the intermediate electrical device.

15. The method of claim 12, wherein the direct and mechanical coupling is configured to avoid a housing structure.

16. The method of claim 12, wherein the intermediate electrical device adjusts, adapts, converts, or augments the first electricity generated by the one or more thin films to a current and voltage combatable with the second electricity generated by the plurality of panels.

17. The method of claim 12, wherein at least one of the one or more thin films comprises cadmium telluride (CdTe), amorphous silicon (a-Si), organic photovoltaic (OPV), or copper indium gallium selenide (CIGS).

18. The method of claim 12, wherein the one or more thin films comprises a front layer, an absorbing layer, and a back layer.

19. The method of claim 18, wherein the absorbing layer comprises a photoactive layer that converts the light within the first band gap to the first electricity, and the photoactive layer comprises the cadmium (Cd) alloy.

20. The method of claim 18, wherein the back layer comprises an electrode that completes a junction that enables the first_electricity generation by the absorbing layer.
